(19) United States
(12) Patent Application Publication
(10) Pub. No.: US 2011/0047434 A1
(43) Pub. Date: Feb. 24, 2011

(54) WIRELESS COMMUNICATION OF TURBO CODED ATSC M/H DATA WITH TIME DIVERSITY

(75) Inventors: GORDON KENT WALKER, Poway, CA (US); Fuyun Ling, San Diego, CA (US)

Correspondence Address: McDermott Will & Emery LLP, 600 13th Street, NW, Washington, DC, 20005-3096, US

(73) Assignee: QUALCOMM Incorporated, San Diego, CA (US)

(21) Appl. No.: 12/913,422

(22) Filed: Oct. 27, 2010

Related U.S. Application Data
(63) Continuation-in-part of application No. 12/165,663, filed on Jul. 1, 2008.
(60) Provisional application No. 61/307,085, filed on Feb. 23, 2010.
(60) Provisional application No. 61/048,487, filed on Apr. 28, 2008.

(51) Int. Cl. H03M 13/05; G06F 11/10

(52) U.S. Cl. 714/752; 714/E11.032

(57) ABSTRACT

In an ATSC M/H wireless broadcast system, data for transmission is turbo encoded into turbo-encoded data blocks. The turbo-coded data blocks are processed for transmission by scheduling a plurality of portions of the block for transmission during respectively corresponding transmit intervals that are temporally separated from one another. The portions of the turbo-encoded blocks may then be transmitted during the respectively corresponding transmit intervals according to the schedule. The turbo-encoded blocks may be interleaved before portions of the blocks are scheduled for transmission.

### CROSS-REFERENCE TO RELATED APPLICATIONS

This utility patent application claims the benefit of priority from U.S. provisional patent Application Ser. No. 61/307,085, entitled “Wireless Communication of Turbo Coded ATSC M/H Data with Time Diversity” filed Feb. 23, 2010.

This utility patent application is a continuation-in-part of, and claims priority to commonly owned U.S. patent application Ser. No. 12/165,663, entitled “Wireless Communication of Turbo Coded Data with Time Diversity” filed Jul. 1, 2008 and published on Oct. 29, 2009 as U.S. Patent Publication No. 2009/0268694, which claims the benefit of priority from U.S. provisional patent Application Ser. No. 61/048,487, filed Apr. 28, 2008 and entitled “Turbo Coding Over Multiple Frames with Better Time Diversity,” the entire contents of all of which are incorporated herein by reference for all purposes.

### BACKGROUND

1. Field

The present disclosure relates generally to communication systems and methods and, more particularly, to wireless communications that use turbo coding.

2. Background

Forward Link Only (FLO) is a digital wireless technology that has been developed by an industry-led group of wireless providers. FLO technology uses advances in coding and interleaving to achieve high-quality reception, both for real-time content streaming and other data services. FLO technology can provide robust mobile performance and high capacity without compromising power consumption. The technology also reduces the network cost of delivering multimedia content by dramatically decreasing the number of transmitters needed to be deployed. In addition, FLO technology-based multimedia multicasting compliments wireless operators' cellular network data and voice services, delivering content to the same cellular mobile terminals used in 3G networks.

Another technology used for mobile multimedia broadcast applications is defined in the Advanced Television Systems Committee (ATSC) Mobile DTV Standard (ATSC S4-131), which is also referred to as ATSC M/H (for mobile/handheld). ATSC M/H provides many of the same broadcast services as FLO in a different data encoding and modulation scheme.

FIG. 1 shows a communications system 100 that creates and broadcasts multimedia content across various networks to a large number of mobile subscribers. The communications system 100 includes any number of content providers 102, a content provider network 104, a broadcast network 106, and a wireless access network 108. The communications system 100 is also shown with a number of devices 110 used by mobile subscribers to receive multimedia content. These devices 110 include a mobile telephone 112, a personal digital assistant (PDA) 114, and a laptop computer 116. The devices 110 illustrate just some of the devices that are suitable for use in the communications systems 100. It should be noted that although three devices are shown in FIG. 1, virtually any number of analogous devices or types of devices are suitable for use in the communications system 100, as would be apparent to those skilled in the art.

The content providers 102 provide content for distribution to mobile subscribers in the communications system 100. The content may include video, audio, multimedia content, clips, real-time and non real-time content, scripts, programs, data or any other type of suitable content. The content providers 102 provide content to the content provider network for wide-area or local-area distribution.

The content provider network 104 comprises any combination of wired and wireless networks that operate to distribute content for delivery to mobile subscribers. In the example illustrated in FIG. 1, the content provider network 104 distributes content through a broadcast network 106. The broadcast network 106 comprises any combination of wired and wireless proprietary networks that are designed to broadcast high quality content. These proprietary networks may be distributed throughout a large geographic region to provide seamless coverage to mobile devices. Typically, the geographic region will be divided into sectors with each sector providing access to wide-area and local-area content.

The content provider network 104 may also include a content server (not shown) for distribution of content through a wireless access network 108. The content server communicates with a base station controller (BSC) (not shown) in the wireless access network 108. The BSC may be used to manage and control any number of base transceiver stations (not explicitly shown) depending on the geographic reach of the wireless access network 108. The base transceiver stations (BTSs) provide access to wide-area and local-area for the various devices 110.

The multimedia content broadcast by the content providers 102 may include one or more services. A service is an aggregation of one or more independent data components. Each independent data component of a service is called a flow. By way of example, a cable news service may include three flows: a video flow, an audio flow, and a control flow.

Services are carried over one of more logical channels. In FLO applications, a logical channel is often referred to as a Multicast Logical Channel (MLC). A logical channel may be divided into multiple logical sub-channels. These logical sub-channels are called streams. Each flow is carried in a single stream. The content for a logical channel is transmitted through the various networks in a physical frame. In FLO applications, the physical frame is often referred to as a superframe.

The air interface used to transmit the physical frames to the various devices 110 shown in FIG. 1 may vary depending on the specific application and the overall design constraints. In general, communication systems employing FLO technology utilize Orthogonal Frequency Division Multiplexing (OFDM), which is also utilized by Digital Audio Broadcasting (DAB), Terrestrial Digital Video Broadcasting (DVB-T), and Terrestrial Integrated Services Digital Broadcasting (ISDB-T). OFDM is a multi-carrier modulation technique that effectively partitions the overall system bandwidth into multiple (N) sub-carriers. These sub-carriers, which are also referred to as tones, bins, frequency channels, etc., are spaced apart at precise frequencies to provide orthogonality. Content may be modulated onto the sub-carriers by adjusting each sub-carrier's phase, amplitude or both. Typically, quadrature phase shift keying (QPSK) or quadrature amplitude modulation (QAM) is used, but other modulation schemes may also be used.

In an ATSC M/H broadcast, data is modulated using Vestigial Sideband Modulation (VSB), specifically 8-VSB which carries 19.5 Mbps of data.

FIG. 2 is a conceptual diagram illustrating an example of a protocol stack 200 for the receiver used in one or more of the devices 110 shown in FIG. 1. The protocol stack is shown with a physical layer 202, a Medium Access Control (MAC) layer 204, a stream player 206, a control layer 208, and a number of upper layers 210. The upper layers 210 provide multiple functions including compression of multimedia content and controlling access to the multimedia content. The control layer 208 is used to process control information that facilitates the operation of the device in the communications system. The receiver also uses the control layer to maintain synchronization of its control information with that in the communications system. The stream layer 206 provides for binding of upper layer flows to streams. The stream layer is at the same level as the control layer in the protocol stack 200 of the receiver. The MAC layer 204 provides multiplexing of packets belonging to different media streams associated with the logical channels. The MAC layer 204 defines the procedures used to receive and transmit over the physical layer 202. The physical layer provides the channel structure, frequency, power output modulation and encoding specification for the air interface.

It is well known that the quality of communication over fading channels may be improved by using time diversity techniques. It is therefore desirable to provide for opportunities to improve time diversity.

### SUMMARY

The various embodiment method and apparatus provide enhancing data transmission in an ATSC M/H wireless communication link. The data transmission enhancement in the ATSC M/H wireless communication link may be achieved by turbo encoding a data block for transmission, scheduling a plurality of portions of the turbo-coded data block for transmission during respectively corresponding transmit intervals that are temporally separated from one another, and transmitting the portions of the turbo-coded data block during the respectively corresponding transmit intervals according to the scheduling.

According to an embodiment, the transmit intervals may be equal in length or separated from one another temporally and the portions may contain single or a plurality of bits. According to a further embodiment, the bits of the turbo-coded block may be re-ordered before the scheduling.

According to an embodiment, the encoding of a data block for transmission may be accomplished using one of a parallel concatenation Turbo encoder, a Serial concatenation Turbo encoder, a low-density parity-check (LDPC) encoder, convolutional coding, and other known method of error correction encoding. The embodiments are not limited to turbo coding, but for ease of reference the term “turbo encoding” is used herein to refer generally to turbo encoding, convolutional encoding and other forms of error correction encoding.

According to an embodiment, an apparatus for processing ATSC M/H data packets to improve transport over an ATSC M/H wireless communication link may include a turbo encoder configured to turbo encode data packets for transmission into a data block, a scheduler configured for scheduling a plurality of portions of the turbo-coded data block for transmission during respectively corresponding transmit intervals that are temporally separated from one another, and a transmitter coupled to said scheduler and configured to transmit said portions of the turbo-coded data block during the respectively corresponding transmit intervals according to said scheduling.

According to an embodiment, the turbo encoder may be selected from the group of a parallel concatenation Turbo encoder, a Serial concatenation Turbo encoder, and a low-density parity-check (LDPC) encoder.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a conceptual diagram illustrating an example of a communications system according to the prior art.

FIG. 2 is a conceptual diagram illustrating an example of a protocol stack for a receiver in the communication system of FIG. 1.

FIG. 3 conceptually illustrates the structure of a prior art MAC packet.

FIG. 4 diagrammatically illustrates a prior art communication system that uses the MAC packet structure of FIG. 3.

FIG. 5 conceptually illustrates a composite packet used according to exemplary embodiments.

FIGS. 6A-6D diagrammatically illustrate a transmit end of a communication system according to exemplary embodiments.

FIGS. 7-10 illustrate results achieved using bit interleaving techniques according to exemplary embodiments of the present work.

FIGS. 11A-11C diagrammatically illustrate a receiver end of a communication system according to exemplary embodiments.

FIG. 12 diagrammatically illustrates turbo decoder control at the receiver end of a communication system according to exemplary embodiments.

FIG. 13 illustrates a broadcast Frame structure of an ATSC M/H broadcast transmission.

FIG. 14 illustrates assignments of multiple broadcast parades to sub-frames within a Frame of an ATSC M/H broadcast transmission.

FIG. 15 is a process component block diagram of a typical ATSC M/H broadcast transmitter system.

FIG. 16 is a process component block diagram of an M/H frame encoder within the ATSC M/H broadcast transmitter system illustrated in FIG. 15.

FIG. 17 is a process component block diagram of a modified ATSC M/H broadcast transmitter system suitable for use with an embodiment.

FIG. 18 is a process flow diagram on an embodiment method that may be implemented by an ATSC M/H broadcast transmitter system for turbo-coding, scheduling and transmitting data.

FIG. 19 is a component block diagram of an ATSC M/H receiver device suitable for use with the various embodiments.

FIG. 20 is a component block diagram of a server suitable for use in an ATSC M/H broadcast system suitable for use with the various embodiments.

### DETAILED DESCRIPTION

The detailed description set forth below in connection with the appended drawings is intended as a description of various embodiments of the invention and is not intended to represent the only embodiments in which the invention may be practiced. The detailed description includes specific details for the purpose of providing a thorough understanding of the invention. However, it will be apparent to those skilled in the art that the invention may be practiced without these specific details. In some instances, well known structures and components are shown in block diagram form in order to avoid obscuring the concepts of the invention.

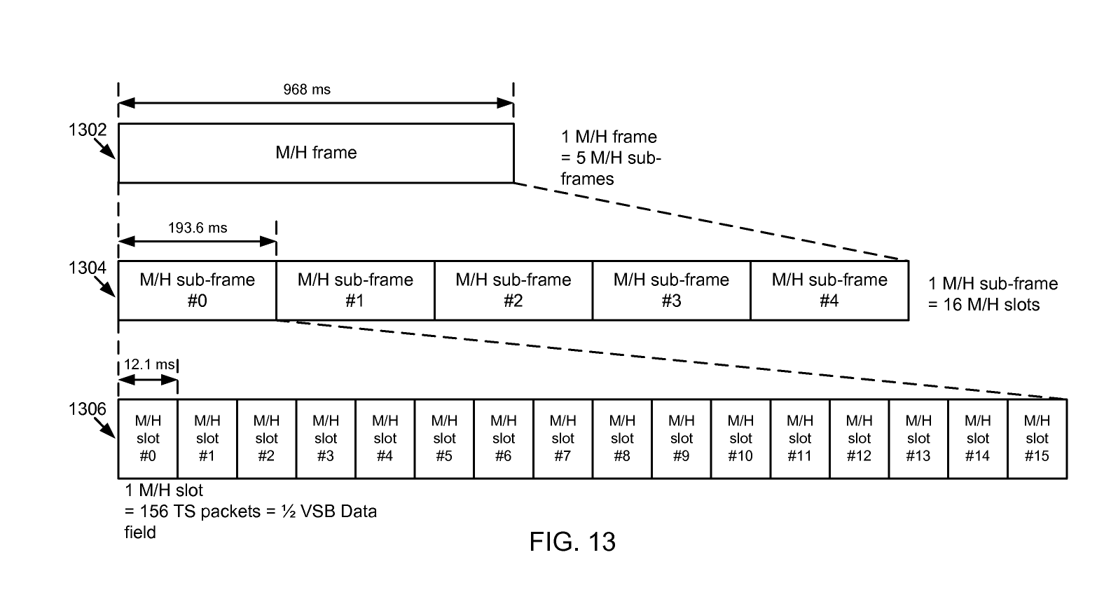

Various concepts herein are described in the context of a FLO technology. While these concepts may be well suited for this application, those skilled in the art will readily appreciate that these concepts are likewise applicable to other technologies. In particular, the embodiments may be applied to the ATSC M/H technology in a very similar manner as described with reference to FIGS. 13-15. Accordingly, any reference to FLO technology is intended only to illustrate the embodiments, with the understanding that such concepts have a wide range of applications.

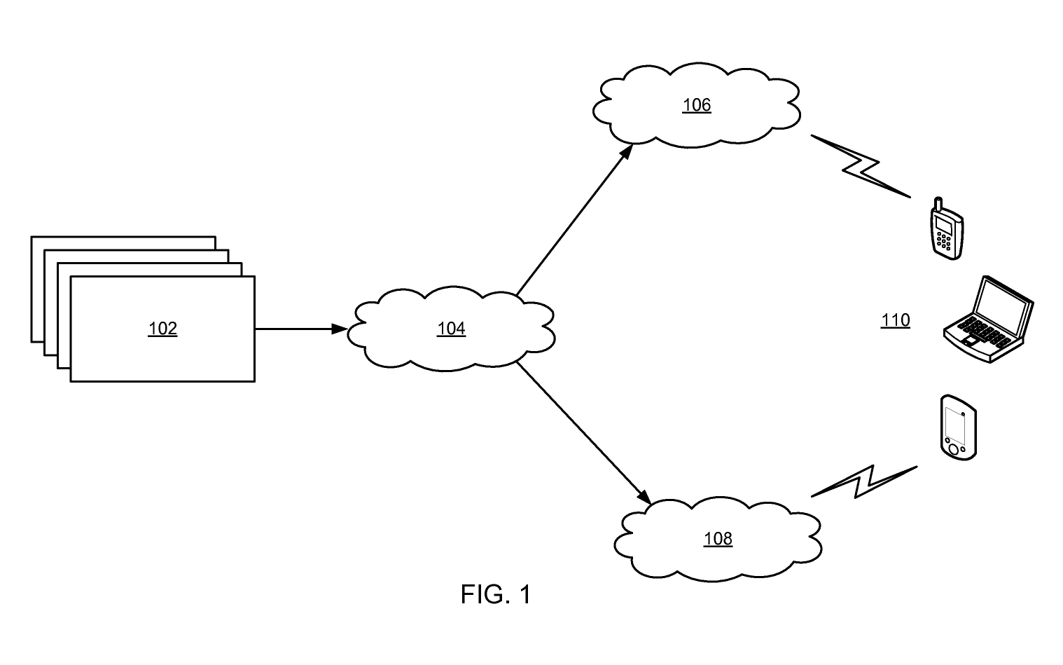

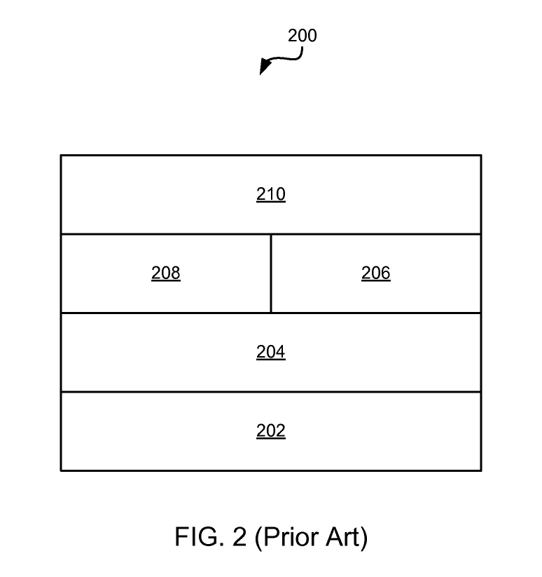

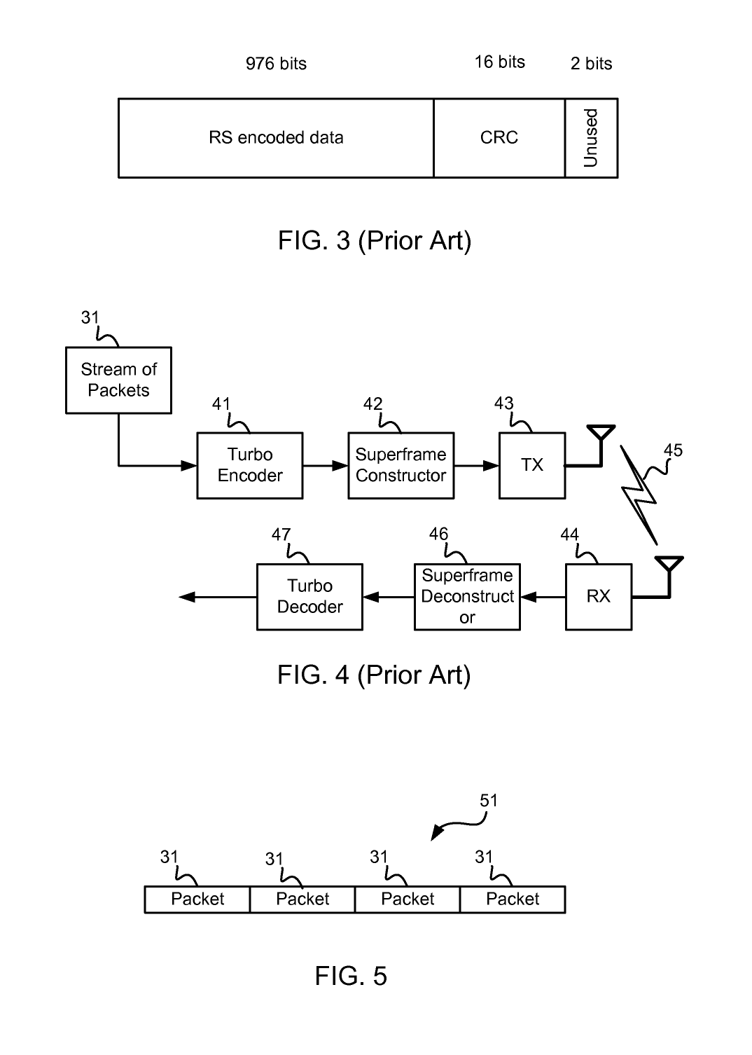

In conventional systems such as described above with respect to FIGS. 1 and 2, the encoding/decoding scheme for detecting and correcting errors utilizes a Reed-Solomon (RS) encoding/decoding in combination with turbo encoding/decoding. At the transmitter, the data bits are Reed-Solomon encoded and organized as Reed-Solomon code blocks. Each Reed-Solomon code block consists of sixteen MAC packets. Each MAC packet contains 994 bits organized as shown at 31 in FIG. 3. The bits of each MAC packet 31 are turbo encoded to produce a corresponding turbo packet. Thus, the turbo encoding of each Reed-Solomon code block produces sixteen turbo packets.

The sixteen turbo packets are distributed equally across a FLO transmission superframe. A transmission superframe has a length of one second, and consists of four frames, each of which has a length of approximately 0.25 seconds. Each frame of a superframe contains four of the aforementioned turbo packets. The turbo encoded bits of each turbo packet are mapped into QPSK, 16QAM, or layered QPSK modulation symbols, which are modulated onto subcarriers of one OFDM symbol (or a few adjacent OFDM symbols) in the same frame. There are 1,200 OFDM signals in a superframe. The encoded bits in a turbo packet are transmitted at the same time if the turbo packet is scheduled on a single OFDM symbol, or they are transmitted temporally closely to one another if the turbo packet is scheduled on adjacent OFDM symbols. As a result, turbo encoding/decoding in conventional FLO technology utilizes very limited time diversity, especially for mobile receivers moving at low speeds. Time diversity is achieved primarily due to the Reed-Solomon encoding/decoding.

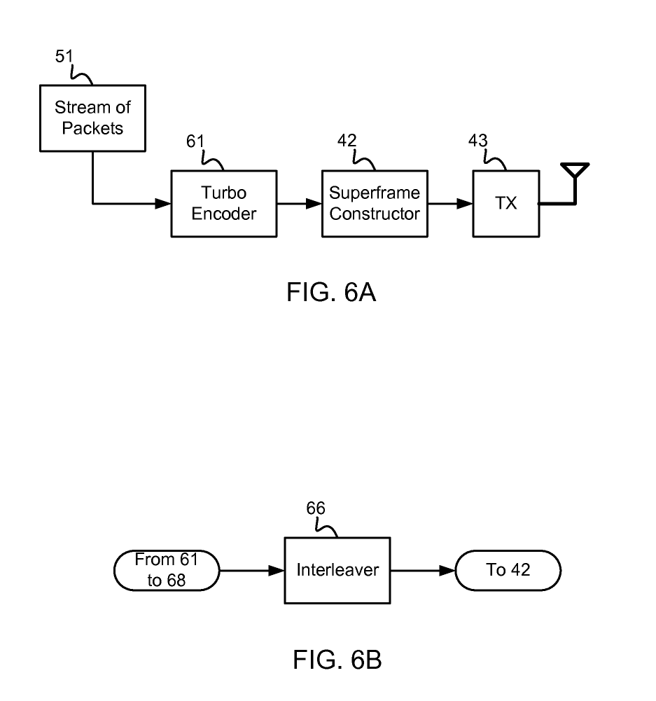

FIG. 4 diagrammatically illustrates details of a prior art communication system (such as the system of FIG. 1) that uses the above-described coding and transmission techniques. A turbo encoder 41 receives a stream of MAC packets 31, sixteen per Reed-Solomon code block, and turbo encodes the MAC packets 31 to produce respectively corresponding turbo packets. A superframe constructor 42 distributes the sixteen turbo packets associated with each Reed-Solomon code block equally across the four frames of a superframe, four turbo packets per frame. The superframe is passed to a transmit unit 43 that transmits the superframes via suitable transmit signaling on a wireless communication link 45. A receive unit 44 receives the transmit signaling, extracts the transmitted superframes, and passes the superframes to a superframe deconstructor 46 that extracts the sixteen turbo packets from the superframe. The superframe deconstructor 46 provides the extracted turbo packets to a turbo decoder 47 where they are turbo decoded.

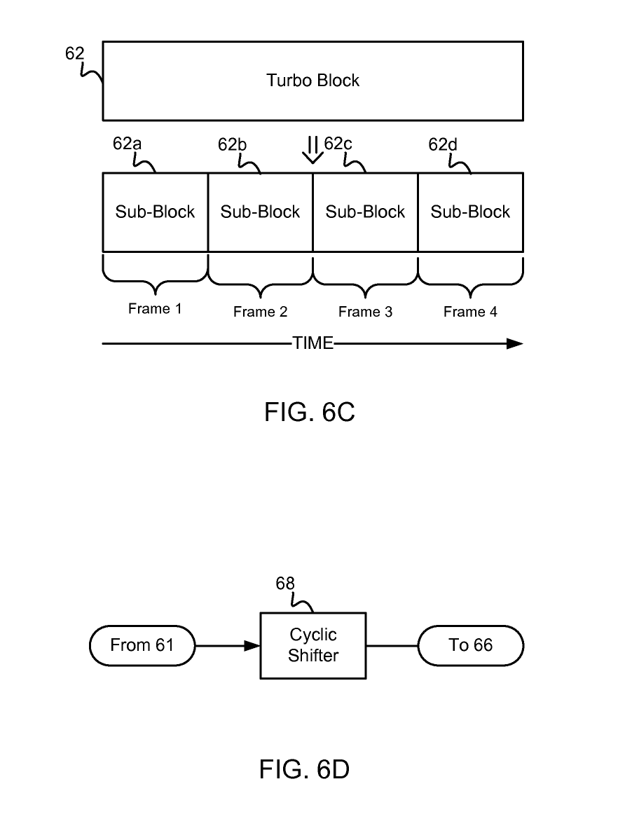

It is known in the art that, by increasing the length of the turbo packets, the performance in an AWGN (additive white Gaussian noise) channel may be improved by a few tenths of a dB. This performance improvement could be obtained, for example, by configuring the turbo encoder to encode four of the MAC packets 31 of the Reed-Solomon code block into a single turbo packet that is four times the length of the conventional turbo packet described above, or encoding eight of the MAC packets 31 into a single turbo packet that is eight times the length of the conventional turbo packet, or encoding all sixteen of the MAC packets of an Reed-Solomon code block into a single turbo packet that is sixteen times the length of the conventional turbo packet. The aforementioned example of four MAC packets 31 grouped together as a longer, composite packet 51 for turbo encoding is shown in FIG. 5. The turbo packets produced by encoding a longer, composite packet such as shown at 51 are also referred to herein as extended length turbo packets or extended length turbo blocks (or simply turbo blocks), in order to distinguish them from a conventional turbo packet produced by turbo encoding a single MAC packet 31. The extended length turbo block produced by turbo encoding the composite packet 51 of FIG. 5 is four times the length of one of the turbo packets produced by the turbo encoder in FIG. 4, and may thus be scheduled for transmission on a single frame within the superframe, using the same OFDM symbols that are occupied by four separate turbo packets in transmissions according to FIG. 4. As mentioned above, the embodiments are not limited to turbo coding, but for ease of reference the term “turbo encoding” is used herein to refer generally to turbo encoding, convolutional encoding and other forms of error correction encoding. Similarly, the term “turbo blocks” is used herein to refer generally to blocks of data resulting from turbo encoding, convolutional encoding and other forms of error correction encoding.

Exemplary embodiments of the present work recognize that, by distributing each extended length turbo block across multiple frames of a superframe, better time diversity and improved system performance under time varying fading channels may be achieved. In some embodiments, the turbo block produced by turbo encoding the composite packet 51 of FIG. 5 is divided into 4 sub-blocks, and each sub-block is scheduled in a different frame of the superframe. The use of sub-blocks scheduled in respectively different frames provides time diversity, so Reed-Solomon coding is eliminated in some embodiments (which frees capacity for transmission of additional user data).

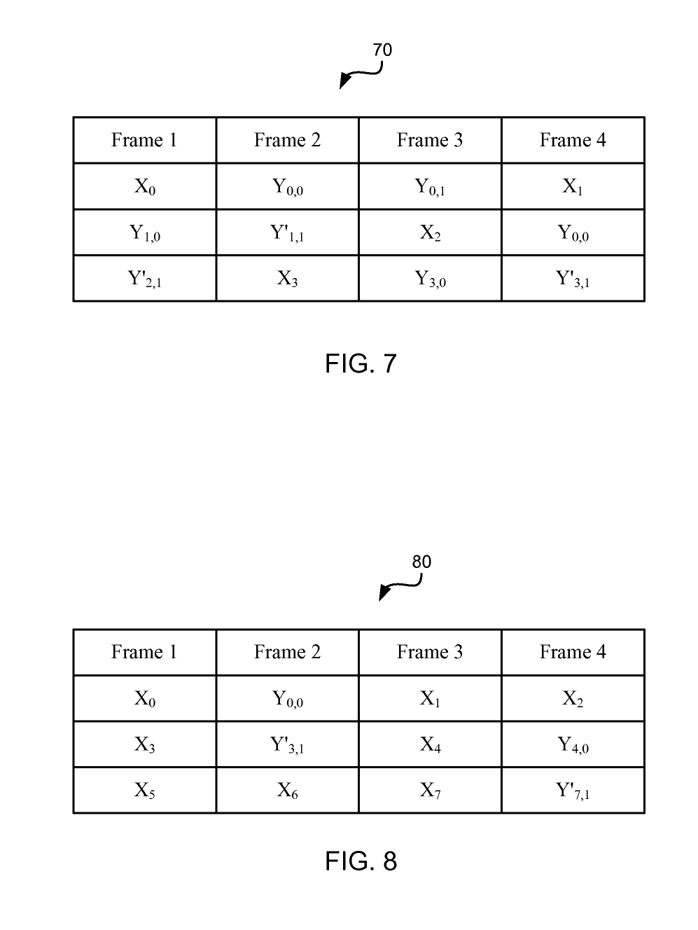

FIG. 6A diagrammatically illustrates the transmit end of a communication system according to exemplary embodiments of the present work. The transmit end of FIG. 6A is generally similar to that of FIG. 4, but uses a turbo encoder 61 that encodes the extended length turbo blocks described above. Taking the example of the composite packets 51 in FIG. 5, a turbo encoder 61 receives a stream of the composite packets, and turbo encodes the composite packets to produce respectively corresponding turbo blocks. FIG. 6A illustrates the aforementioned embodiments wherein each turbo block (which is four times the length of the aforementioned conventional turbo packet) is scheduled by superframe constructor 42 for transmission in a respectively corresponding frame within the superframe. The superframe is passed to the transmit unit 43 for transmission as in FIG. 4.

FIGS. 6B and 6C diagrammatically illustrate the aforementioned exemplary embodiments wherein each turbo block is divided into 4 sub-blocks, and each sub-block is scheduled in a different frame of the superframe. An interleaver 66 in FIG. 6B receives the turbo blocks, for example, turbo blocks 62 (FIG. 6C) produced from the composite packets 51 of FIG. 5, from the turbo encoder 61. In some embodiments, the interleaver 66 divides each of the turbo blocks into four equally-sized sub-blocks 62a, 62b, 62c, 62d as shown in FIG. 6C, and interleaves the sub-blocks 62a, 62b, 62c, 62d appropriately to cause the superframe constructor 42 to schedule each sub-block 62a, 62b, 62c, 62d in a respectively different frame of the superframe. For example, as shown in FIG. 6C, the first of the four sub-blocks 62a may be scheduled for the first frame (frame 1) of the superframe, the second of the four sub-blocks 62b may be scheduled for the second frame (frame 2), and so on. This particular scheme of apportioning the sub-blocks 62a, 62b, 62c, 62d among the frames is generally referred to herein as a round-robin scheme. Taking the aforementioned example of a FLO transmission superframe, the transmitted sub-blocks 62a, 62b, 62c, 62d in FIG. 6C are separated from each other in time by approximately 0.25 seconds.

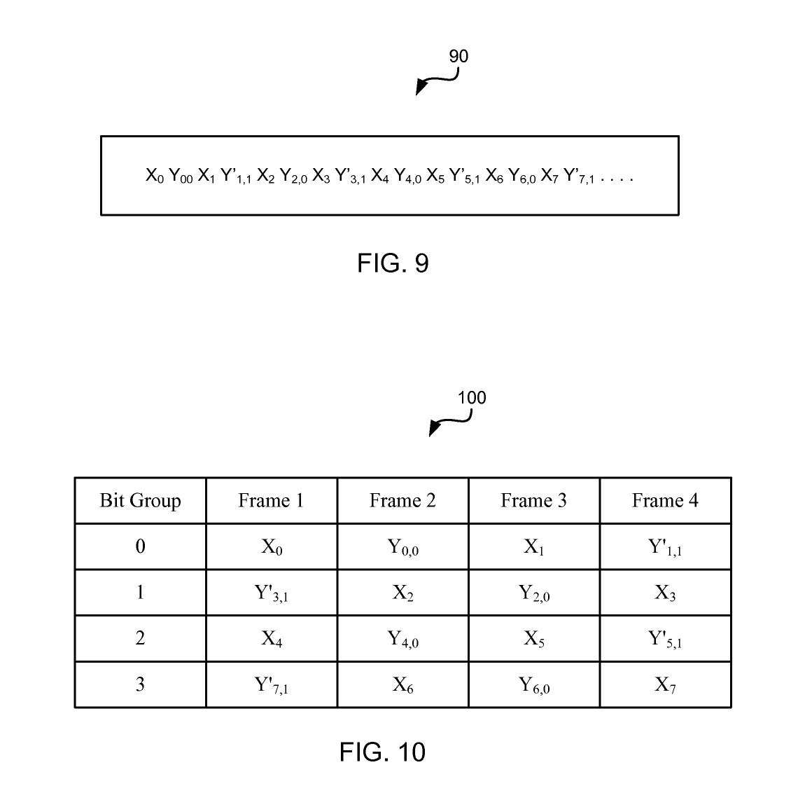

Some embodiments achieve additional time diversity by applying bit-level interleaving to each turbo block. In such embodiments, the interleaver 66 of FIG. 6B interleaves the bits of the turbo block appropriately to cause the scheduler 42 to schedule adjacent bits of the turbo block in different frames. FIGS. 7 and 8 illustrate tables 70 and 80, respectively, including the results of this bit-level interleaving according to exemplary embodiments of the present work.

Some conventional systems such as shown in FIGS. 1 and 2 support turbo code rates of 1/5, 1/3, 1/2, and 2/3, where the latter three code rates are punctured from the 1/5 code rate. In one conventional example of a rate 1/3 turbo code, the output bits of the turbo encoder are in the order of X₀, Y_{0,0}, Y′_{0,1}, X₁, Y_{1,0}, Y′_{1,1}, X₂, Y_{2,0}, Y′_{2,1}, X₃, Y_{3,0}, Y′_{3,1}, where the Xᵢ are the systematic bits, the Y_{i,0} are the corresponding first parity bits of the first constituent code, and the Y′_{i,1} are the corresponding second parity bits of the second constituent code.

For purposes of exposition, the 1/3 rate turbo code will be used as an example, taken together with the aforementioned example of four frames per superframe. In this exemplary scenario, some embodiments of the interleaver 66 use a round-robin bit interleaving scheme to deterministically separate adjacent bits of the turbo block into different frames. In the round-robin scheme, the first bit of the turbo block is scheduled in the first frame (frame 1), but the second bit is scheduled in the second frame (frame 2), the third bit is scheduled in the third frame (frame 3), and the fourth bit is scheduled in the fourth frame (frame 4). The process then wraps back around so the fifth bit is scheduled in frame 1, and so on. The result of this re-ordering of bits of the turbo-coded block before scheduling is shown in FIG. 7 in table 70, where, for example, successive adjacent bits of the turbo block are allocated to respectively different frames of a superframe. Table 80 in FIG. 8 illustrates an example of results obtained using the round-robin bit interleaving scheme for a rate 2/3 turbo code with four frames per superframe.

Table 90 in FIG. 9 provides an example of output bits produced by a rate 1/2 turbo encoder. It can be seen from FIG. 9 that, using the round-robin scheme, half of the systematic bits would be scheduled in frame 1, with the other half of the systematic bits scheduled in frame 3. This phenomenon also in fact occurs in the rate 2/3 code example shown in FIG. 8. For the rate 1/2 code, however, some embodiments apply a single cyclic bit shift to every other group of four bits in the turbo block, beginning with the fifth through eighth bits, and again for the thirteenth through sixteenth bits, and so on. This cyclic bit shifting is performed before the round robin interleaving scheme is implemented. The result obtained by using the cyclic bit shift for the rate 1/2 code example of FIG. 9, with four frames per superframe and round-robin bit interleaving, is shown in FIG. 10 in table 100. Bit group 1 contains the cyclic-shifted version of the fifth through eighth bits (Y′_{3,1} cycled around to the location where X₂ would otherwise appear), and Bit group 3 contains the cyclic-shifted version of the thirteenth through sixteenth bits (Y′_{7,1} cycled around to the location where X₆ would otherwise appear). Table 100 in FIG. 10 shows that, with the cyclic bit shifts, the systematic bits are advantageously distributed across all four frames of the superframe, rather than being confined to frames 1 and 3.

FIG. 6D diagrammatically illustrates exemplary embodiments that employ the above-described cyclic bit shifting. A cyclic bit shifter 68 receives each turbo block from the turbo encoder 61, and produces a corresponding cyclic shifted block wherein selected groups of bits are cyclic shifted among themselves by a selected amount. This cyclic shifted block is provided to the interleaver 66, which produces a corresponding bit interleaved block in the manner described above. The bit interleaved block is then processed by the superframe constructor 42.

It will be appreciated from FIGS. 6A-6C that, in various embodiments, various combinations of the interleaver 66, the cyclic bit shifter 68 and the superframe constructor 42 cooperate to serve as a scheduler that schedules the content of the turbo blocks as desired for transmission by the transmit unit 43.

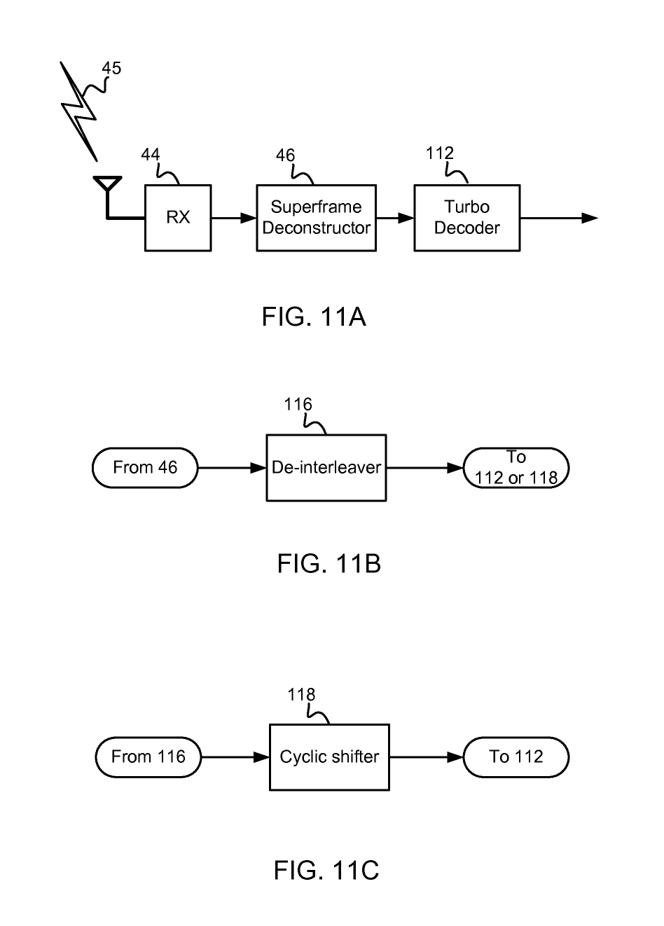

FIG. 11 diagrammatically illustrates exemplary embodiments of a receiver end arrangement for use in a communication system having a transmit end arrangement such as shown in and described with respect to FIG. 6A. The receiver end of FIG. 11 is generally similar to the receiver end shown in and described with respect to FIG. 4, but includes a turbo decoder 112 that decodes the extended length turbo blocks received from a superframe deconstructor 46. The turbo decoder 112 produces received versions of the composite packets, for example, the composite packets 51 of FIG. 5, that were turbo encoded by the turbo encoder 61 at the transmit end of FIG. 6A.

FIG. 11A diagrammatically illustrates exemplary receiver end embodiments that support interleaving techniques such as described above with respect to the interleaver 66 of FIG. 6B. In various embodiments, the de-interleaver 116 of FIG. 11B receives the turbo blocks from the superframe deconstructor 46, and performs de-interleaving operations complementary to the interleaving operations performed by the interleaver 66 of FIG. 6B. The de-interleaver 116 provides its results, in various embodiments, to either the turbo decoder 112 of FIG. 6A, or to a cyclic shifter 118 shown in FIG. 11C and described below.

FIG. 11C diagrammatically illustrates exemplary receiver end embodiments that support cyclic bit shifting techniques such as described above with respect to the cyclic shifter 68 of FIG. 6D. In various embodiments, the cyclic shifter 118 of FIG. 11C receives the output of de-interleaver 116, and performs cyclic shifting operations complementary to the cyclic shifting operations performed by the cyclic shifter 68 of FIG. 6D. The cyclic shifted results produced by the cyclic shifter 118 are provided to the turbo decoder 112.

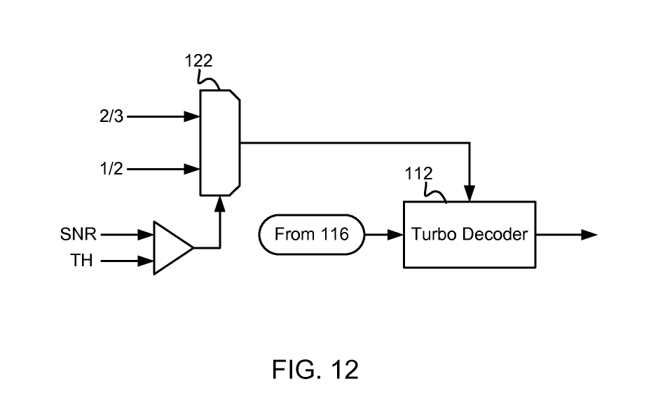

As mentioned above with respect to FIG. 9, if a rate 1/2 turbo code with round-robin bit interleaving is implemented without the cyclic shifting provided at 68 in FIG. 6D, all systematic bits will be confined to frames 1 and 3 of the superframe. Moreover, as seen from FIG. 9, all of the parity bits are transmitted in frames 2 and 4. Exemplary embodiments of the present work exploit this phenomenon in situations where the signal-to-noise ratio (SNR) associated with the communication link 45 is acceptably high, by implementing rate 2/3 turbo decoding at the receiver end, using only the parity bits transmitted in frame 2, and ignoring the remaining parity bits transmitted in frame 4. Because the portions of the turbo block contained in frame 4 are ignored, the receiver end need not “wake up” to receive them during frame 4, thereby achieving power savings, which may be important if the receiver is a portable (e.g., hand-held) device. FIG. 12 diagrammatically illustrates such a receiver end arrangement according to exemplary embodiments of the present work.

As shown in FIG. 12, a selector 122 provides turbo decoder 112 (see also FIG. 11) with an indication regarding whether rate 1/2 or rate 2/3 turbo decoding is to be used. The selection made by selector 122 is controlled by the output of a comparator 121 that compares the SNR currently associated with the communication link 45 to a threshold value TH. If the SNR exceeds the threshold value TH, the comparator output causes the selector 122 to select rate 2/3 turbo decoding, thereby instructing the turbo decoder 112 to use rate 2/3 turbo decoding, and to ignore the frame 4 parity bits. If the SNR does not exceed the threshold TH or if the decoding of the rate 2/3 code fails, the comparator output causes the selector 122 to select rate 1/2 turbo decoding by including the received signal samples in the fourth frame, thereby instructing the turbo decoder 112 to use rate 1/2 turbo decoding as usual.

The various embodiments may be implemented in ATCS M/H which, due to its data structure may also benefit from the advantages provided by the embodiments. In ATSC M/H, data comprising a broadcast program is transmitted in M/H encapsulation transport packets, which are organized into “groups” consisting of 118 consecutive M/H encapsulation packets. A sequence of programs (e.g., IP streams) under the control of the broadcaster which can be broadcast as part of a schedule is referred to as an “M/H service.” M/H services are organized into an “ensemble” which is a collection of M/H services which all have the same Forward Error Correction (FEC) coding. Each ensemble may be coded to a different level of FEC to meet different application requirements, so each ensemble may be encoded using an independent Reed-Solomon Frame. Ensembles are organized into “parades” which are a sequence of transmitted M/H groups (in slots) which carries an ensemble.

As illustrated in FIG. 13, data is transmitted in ATSC M/H in superframes 1300, which are referred to simply as “Frames” in the ATSC M/H specification. As shown in row 1302, the M/H Frame is a basic time period that carries one or more M/H Parades. Each Parade is derived from either one or two Reed-Solomon Frames. One M/H Frame carries main data and M/H data (encapsulated in MHE packets) equivalent in size to exactly 20 VSB data frames. However, the boundaries of the M/H Frame are offset from VSB Frame boundaries, as explained below. As shown in row 1304, the M/H Frame consists of 5 consecutive Sub-Frames, respectively numbered 0, 1, 2, 3, and 4. Thus, each Sub-Frame contains the same amount of data as 4-VSB data frames (8-VSB data fields). As shown in row 1306, each Sub-Frame consists of 16 consecutive M/H Slots, respectively numbered 0, 1, 2, . . . 15. Each M/H Slot consists of 156 TS packets or equivalently 156 data segments (at the symbol level), or equivalently one half of a VSB data field. When packets from a given M/H Slot are processed into interleaved data segments, the symbols from that Slot are distributed throughout more than 156 data segments. The duration of an M/H Slot is approximately 12.1 ms, and the duration of an M/H Sub-Frame is approximately 193.6 ms. The duration of a M/H Frame is the same as 20 VSB data frames (i.e., approximately 968 ms), but the M/H Frame boundaries are offset from VSB data frame boundaries.

The M/H Slot is the basic time period for multiplexing of M/H data and main data. After M/H pre-processing, M/H data is formatted as a Group of 118 consecutive MHE packets which encapsulate the M/H service data. A particular Slot may contain M/H data, or may consist of only main data. If an M/H Group is transmitted during an M/H Slot, then the first 118 TS packets in the Slot is an M/H Group, and the remaining 38 packets is main TS packets. If there is no M/H Group in an M/H Slot, the M/H Slot consists of 156 main TS packets.

As required in A/53 Part 2:2007, each VSB data frame consists of two VSB data fields, each containing 313 data segments. The first data segment of each VSB data field is a unique synchronizing signal (field sync) and includes the training sequence used by non-M/H as well as M/H receivers. The remaining 312 data segments each carry the equivalent of the data from one 188-byte Transport Stream (TS) packet plus its associated FEC overhead. The start of the M/H Slot is offset in its position relative to the start of a VSB data frame.

Each M/H Frame is composed of 5 M/H subframes. Each subframe is composed of 16 Slots. A Slot consists of 156 TS packets (before byte interleaving). A slot may consist of only legacy TS packets, or may be assigned to carry a Group of 118 M/H-carrying MHE packets plus 38 legacy TS packets. Once the assignment is made, the M/H data is transmitted in time order of available slots. There are also defined rules for the placement of Groups belonging to single or multiple Ensembles.

The number of Groups allotted per M/H Frame is a multiple of 5, and the Group allotment and assignment is identical for all M/H Sub-Frames in an M/H Frame. An M/H Parade is a collection of M/H Groups, contained within one M/H Frame. The portion of a Parade within a Sub-Frame consists of a collection of consecutively numbered Groups. The structure of a Parade in terms of its constituent Group numbers and Slot numbers within a Sub-Frame is replicated in all Sub-Frames of an M/H Frame (although the data contents of the Groups differ among the Sub-Frames).

The starting Group number for the first Parade to which Group numbers are assigned is zero. The starting Group number of a succeeding Parade is the next higher Group number after the Group numbers for all preceding Parades have been assigned. An M/H Parade carries data from one or two particular Reed-Solomon Frames depending on a Reed-Solomon Frame mode. The Reed-Solomon Frame is a packet-level FEC structure for the M/H data. Each Reed-Solomon Frame carries, and FEC encodes, an M/H Ensemble, which is a collection of M/H services providing the same quality of service (QoS).

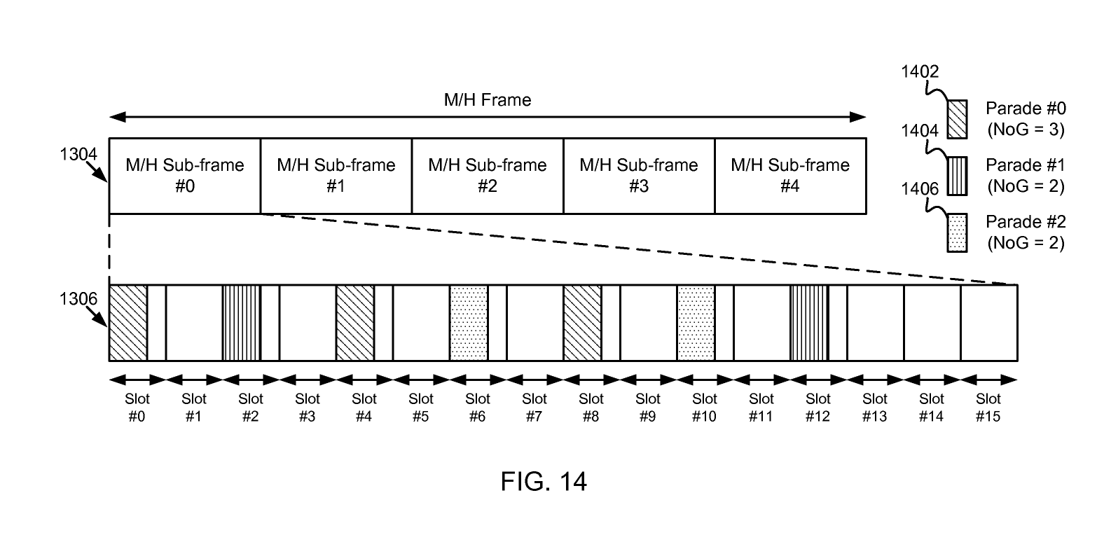

Multiple M/H Parades can be transmitted with main data within an M/H Frame. FIG. 14 shows an example of multiple-Parade transmission. Row 1304 shows the five M/H Sub-Frames of an M/H Frame. One Sub-Frame is expanded to 16 Slots showing the detailed Parade pattern. The 16 Slots and the detailed Parade pattern are shown in row 1306. All five Sub-Frames shown in row 1302 follow the same pattern. The example in FIG. 14 shows three M/H Parades 1402, 1404, 1406 in an M/H Frame. The first Parade 1402 has 3 Groups per M/H Sub-Frame and its Group positions are determined by a simple formula. The second Parade 1404 has 2 Groups per M/H Sub-Frame and its allocated Slot numbers are determined by substituting the Group number i from 3 to 4 in the formula. In a similar manner, the Group positions of the third Parade 1406 are obtained by substituting the Group number i from 5 to 6 in the formula. The M/H Frame organization can be changed M/H Frame by M/H Frame. This allows adjustment of Ensemble data rates on a frequent and flexible basis. The Number of Groups per M/H Sub-Frame (NoG) for an M/H Parade 1402, 1404, 1406 ranges from 1 to 8 and therefore the number of Groups per an M/H Frame for a Parade ranges from 5 to 40 with a step of 5.

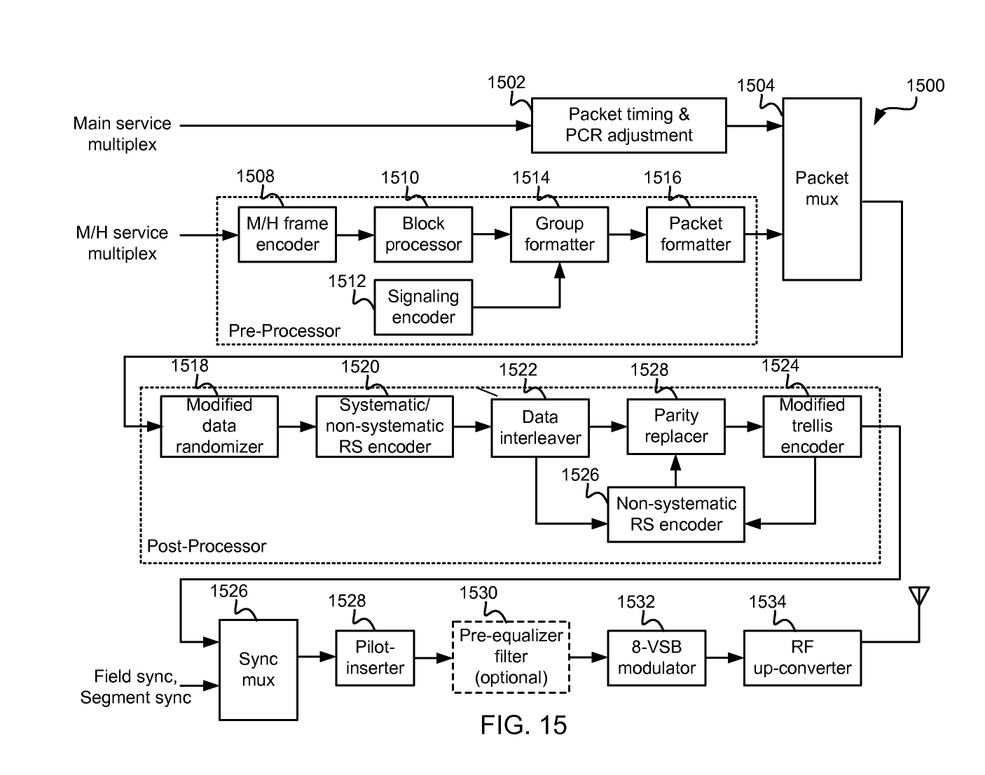

FIG. 15 is a functional block diagram of an ATSC M/H transmission system. The M/H transmission system receives two sets of input streams; one consists of the MPEG transport stream (TS) packets of the main service data, and the other consists of the M/H service data. At a high level, the function of the M/H transmission system is to combine these two types of streams into one stream of MPEG TS packets and process and modulate them into the normal ATSC trellis-coded 8-VSB signal.

Time division multiplexing of main and M/H data may introduce changes to the time of emission of the main service stream packets compared to the timing that would occur with no M/H stream present. Such temporal displacements may be compensated for at the combining point so that the emitted signal complies with the MPEG and ATSC standards to support legacy receivers. These functions may be performed by the Packet timing and PCR adjustment 1502 function.

The M/H frame encoder 1508 encodes ensembles into primary and secondary Reed-Solomon frames, randomizes the M/H data for spectral performance and adds two-dimensional Reed-Solomon CRC encoding. The block processor 1510 adds convolutional coding and symbol interleaving to the M/H data to provide added robustness. The signal encoder 1512 adds fast information channel (FIC) and transmission parameter channel (TPC) control data, which is coded and interleaved for robustness. The group formatter 1514 and the packet formatter 1516 arrange the input for the interleaver so that the output is in the desired form. The output of these blocks is processed by the packet multiplexer 1504 which multiplexes M/H data and main service data.

The modified data randomizer 1518 is of the same legacy as the 8-VSB transmitter, except that it skips over the M/H data which was randomized in the M/H frame encoder. The systematic/non-systematic Reed-Solomon (RS) encoder 1520 optimizes location of parity bytes for M/H data while maintaining compatibility with legacy 8-VSB receivers. The data interleaver 1522 is the same as the legacy 8-VSB transmitter. The modified trellis encoder 1524 inserts M/H training signals to provide robustness and high Doppler conditions, but otherwise is the same as the legacy 8-VSB transmitter. The non-systematic Reed-Solomon encoder 1526 and the parity replacer 1528 recalculates certain Reed-Solomon parity bytes to replace those calculated prior to the trellis initialization.

The remaining functional components in the transmitter system are the same as the legacy 8-VSB transmitter system. These may include an optional pre-equalizer filter 1530, a 8-VSB modulator 1532 and the radio frequency up-converter 1534 which together condition the signal for transmission.

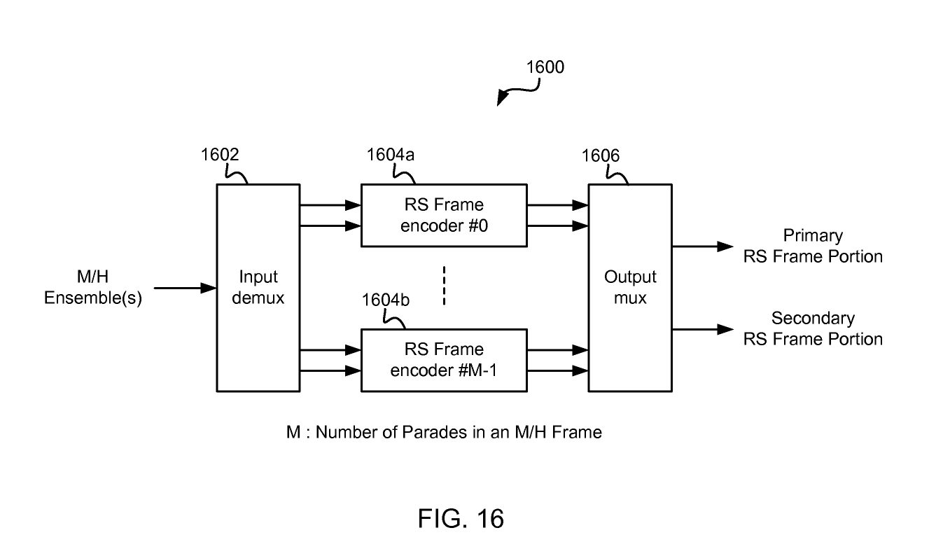

FIG. 16 shows a conceptual block diagram 1600 of the M/H Frame encoder 1508. The input demultiplexer 1602 separates the input Ensembles and routes the corresponding Ensemble(s) into each Reed-Solomon Frame encoder 1604a, 1604b. The M/H Frame encoder 1508 includes the same number of Reed-Solomon Frame encoders 1604 as the number of Parades in an M/H Frame. Each Reed-Solomon Frame encoder 1604a, 1604b builds one or two Reed-Solomon Frames for each Parade and separates each Reed-Solomon Frame into several portions. Each segmented portion of the Reed-Solomon Frame corresponds to the amount of data carried by a Group. The output multiplexer 1606 puts the RS Frame portions constructed by the RS Frame Encoders 1604a, 1604b into the order required by the block processor 1510 (shown in FIG. 15).

A Reed-Solomon Frame encoder 1604 operates in one of two modes according to the Reed-Solomon Frame mode assigned to that encoder. In the case of Reed-Solomon Frame mode=‘00’ (Single Frame), the Reed-Solomon Frame encoder 1604 produces one (primary) Reed-Solomon frame, which will be transmitted in Regions A,B,C, and D of M/H Groups. In the case of Reed-Solomon frame mode=‘01’ (Dual Frame), the Reed-Solomon Frame encoder 1604 encodes two Reed-Solomon Frames, a primary Reed-Solomon Frame, which will be transmitted in Regions A and B of M/H Groups, and a secondary Reed-Solomon Frame, which will be transmitted in Regions C and D of M/H Groups.

In the case of Reed-Solomon frame mode=‘00’, a Reed-Solomon Frame encoder 1604 builds one Reed-Solomon Frame for each M/H Parade by receiving a primary M/H Ensemble. In the case of Reed-Solomon frame mode=‘01’, a Reed-Solomon Frame encoder 1604 builds two Reed-Solomon Frames for each M/H Parade by receiving a primary and a secondary M/H Ensemble. Each M/H Ensemble is processed through an M/H Randomizer (not shown) and then is FEC coded using both Reed-Solomon and CRC codes in a cross-interleaved manner to build a Reed-Solomon Frame.

In embodiments appropriate for ATSC M/H, the M/H data are organized as Turbo information packets. Each of these information packets are randomized, interleaved and encoded by a Turbo encoder to form a Turbo code block. A single or a combination of plural number of the resulting turbo code blocks are interleaved by a channel interleaver and divided into five equally-sized sub-blocks (since there are five sub-frames per ATSC M/H Frame). Each sub-block is included in one or more M/H slots in a respectively different sub-frame of the ATSC M/H Frame. For example, the first of the five sub-blocks may be scheduled for the first subframe (subframe 0) of the Frame, the second of the five sub-blocks may be scheduled for the second subframe (subframe 1), and so on. This assignment scheme of apportioning the sub-blocks among the sub-frames ensures the transmitted sub-blocks are separated from each other in time by approximately 0.2 seconds in ATSC M/H. The M/H frames so formed are then muxed with Sync signals and processed as in a conventional ATSC M/H transmitter.

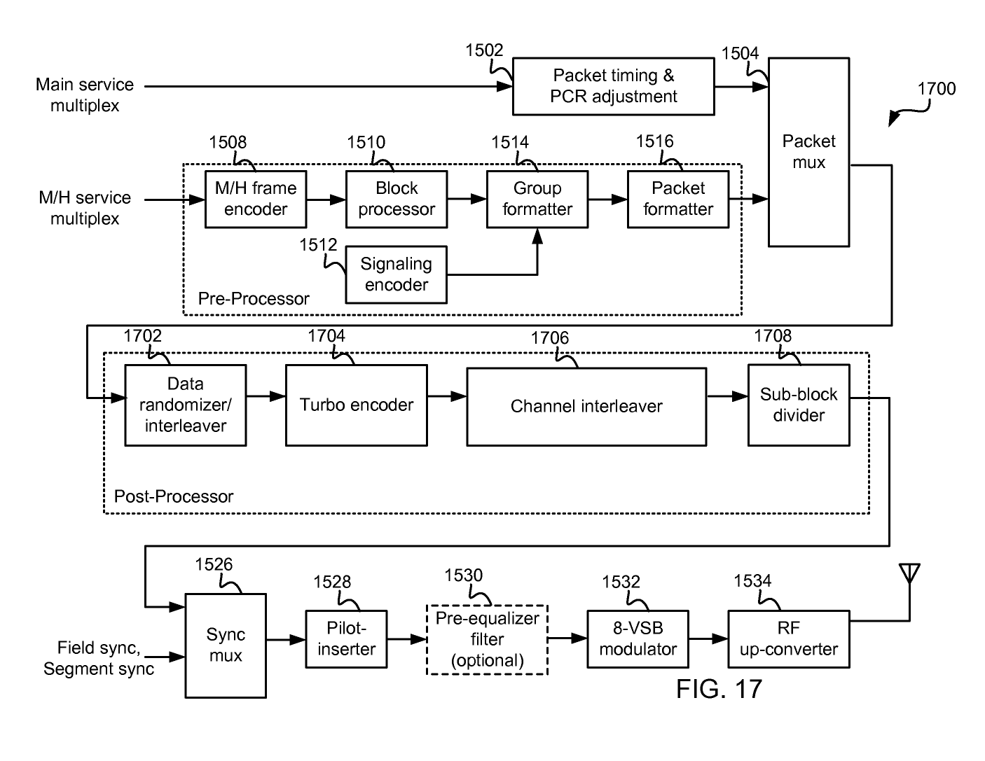

A transmitter system suitable for implementing this embodiment is illustrated in FIG. 17 which includes a post-processor portion that accepts data packets from the packet multiplexer 1504 into a data randomizer/interleaver 1702. The data randomizer/interleaver 1702 passes randomized data packets to a turbo encoder 1704 that generates turbo code blocks that are passed to a channel interleaver 1706 which provides data blocks to a sub-block divider 1708. The remaining elements of the system are consistent with those described above with reference to FIG. 15.

The decoding process in receiver devices may proceed in a manner similar to that described above except that the receiver is configured to recover the five sub-blocks. For example, some Reed-Solomon decode methods may be applied to received encoded ATSC M/H data.

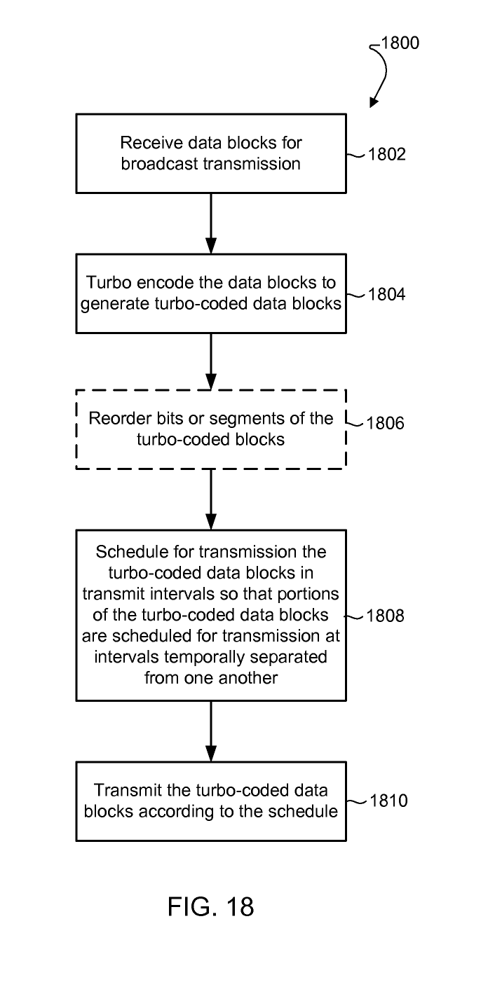

Operations performed in hardware, software or partially in hardware and software of an ATSC M/H broadcast transmitter system in an embodiment is illustrated in method 1800 shown in FIG. 18. In method 1800 at step 1802, an ATSC M/H broadcast transmitter system may receive data blocks for broadcast transmission. In step 1804, the received data blocks may be turbo encoded (or other form of convolutional or error correction encoding) to generate turbo-encoded data blocks. Such turbo-encoding may be accomplished using a parallel concatenation Turbo encoder, a Serial concatenation Turbo encoder, a low-density parity-check (LDPC) encoder, or another known encoder. In optional step 1806, bits or segments of bits of the turbo-coded blocks by be re-ordered, pseudo-randomized or interleaved in a reversible manner in order to enhance transmission reliability. In step 1808, the transmission system may turbo-encoded data blocks for transmission in a manner that ensures that the blocks are temporally separated one from another in time. Specifically, the transmission system may schedule one or more groups or portions of the turbo-encoded data blocks for transmission in respective transmission intervals separated one from another in time. In step 1810, the ATSC M/H broadcast transmitter system may then transmit the turbo-coded data blocks within their respective corresponding transmit intervals according to ATSC M/H broadcast standards. In this method 1800, the transmit intervals may be equal in length and/or may be temporally separated one from another equally (i.e., transmitted at intervals that are equally separated in time). In scheduling portions of the turbo-encoded data blocks for transmission the portions may be single bits or groups of multiple bits.

Those of skill in the art would understand that the description of the above embodiment can be modified without departing from the scope of the claims. For example, the parallel concatenation Turbo encoder described in the foregoing embodiments can be replaced with another type of encoder, including, but not limited to, a serial concatenation Turbo encoder, a low-density parity-check (LDPC) encoder, a convolutional encoder, or any encoder of an error correcting code. As mentioned above, the term “turbo encoding” is used herein to refer generally to turbo encoding, convolutional encoding and other forms of error correction encoding.

The foregoing descriptions of the embodiments refer to the application to ATSC M/H data. However, the embodiment methods and systems may also be applied to ATSC formatted data, and thus, the references to ATSC M/H are not intended to exclude application of the embodiments to ATSC formatted broadcast transmissions.

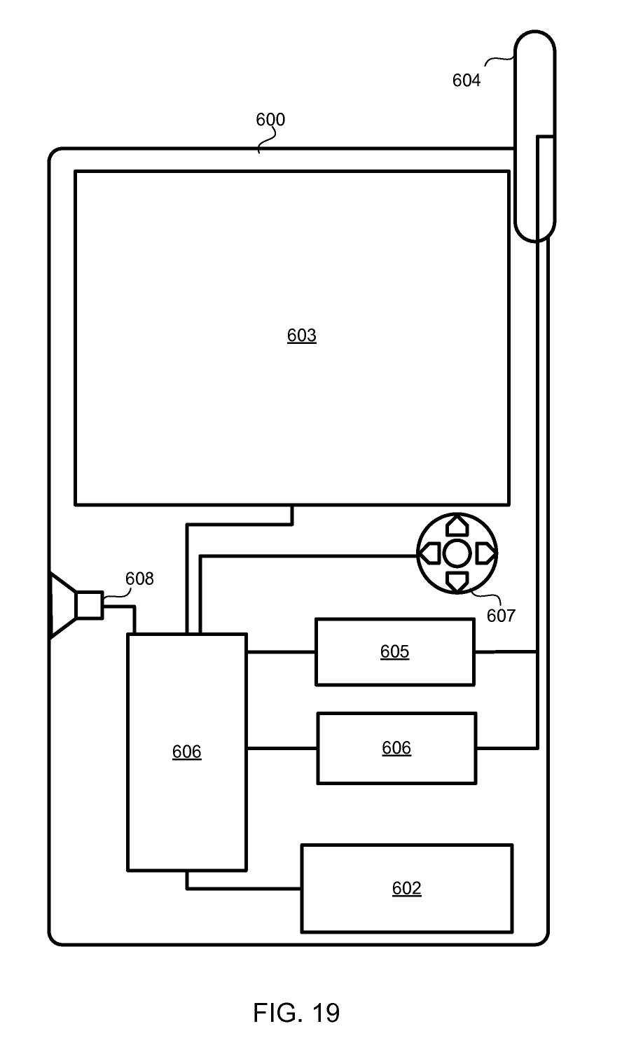

FIG. 19 is a system block diagram of a receiver device suitable for receiving data encoded and interleaved in accordance with any of the embodiments. A typical receiver device 600 may include a processor 601 coupled to internal memory 602, a display 603, and to a speaker 608. Additionally, the receiver device 600 will include an antenna 604 for sending and receiving electromagnetic radiation that may be connected to a wireless data link and/or cellular telephone transceiver 605 coupled to the processor 601 and a mobile multimedia broadcast receiver 606 coupled to the processor 601. Receiver devices 600 typically also include menu selection buttons or rocker switches 607 for receiving user inputs.

Decoding of ATSC M/H signals using the various embodiments may be performed by the multimedia receiver 606 and portions of the processor 601, 701 and memory 602, 702. Alternatively, dedicated modules within or coupled to the multimedia receiver 606 may perform the embodiment methods. In other alternative embodiments, the methods may be performed by the processor 601, 701 after the ATSC M/H signal is received and demodulated by the multimedia receiver 606.

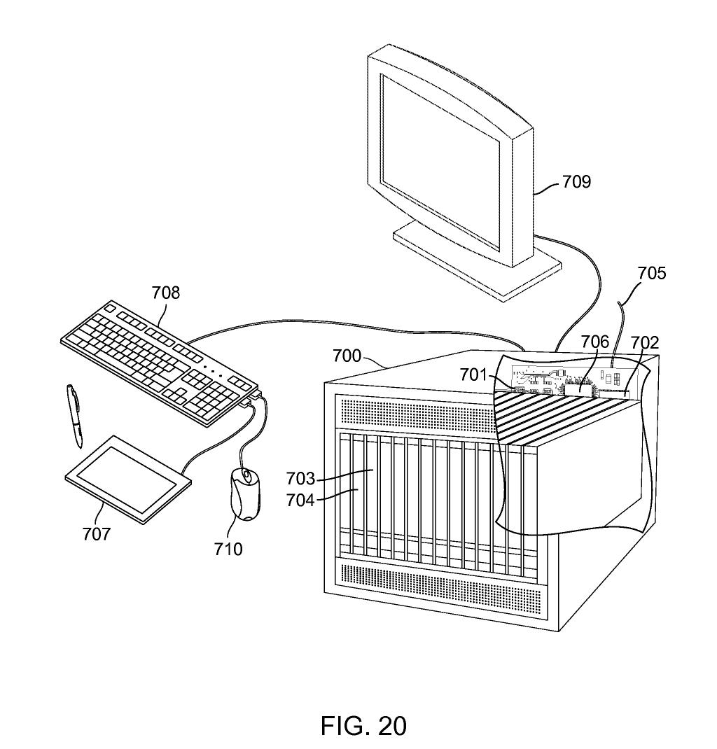

The various embodiments on the broadcast side described above may be implemented on any of a variety of commercially available server devices, such as the server 700 illustrated in FIG. 20. Such a server 700 typically includes a processor 701 coupled to volatile memory 702 and a large capacity nonvolatile memory, such as a disk drive 703. The server 700 may also include a floppy disc drive and/or a compact disc (CD) drive 704 coupled to the processor 701. The server 700 may also include network access ports 706 coupled to the processor 701 for establishing data connections with a network 705, such as the Internet and local networks for communicating with broadcast system equipment. To allow users to communicate with the server 700, the server 700 may include a keyboard 708, monitor 709, touchpad 707 or pointing device 710 as is well known in the computer arts.

The processor 601, 701 may be any programmable microprocessor, microcomputer or multiple processor chip or chips that can be configured by software instructions (applications) to perform a variety of functions, including the functions of the various embodiments described herein. In some mobile receiver devices, multiple processors 601 may be provided, such as one processor dedicated to wireless communication functions and one processor dedicated to running other applications. Typically, software applications may be stored in the internal memory 602, 702 before they are accessed and loaded into the processor 601, 701. In some servers, the processor 701 may include internal memory sufficient to store the application software instructions. In some mobile receiver devices, the secure memory may be in a separate memory chip coupled to the processor 601. The internal memory 602, 702 may be a volatile or nonvolatile memory, such as flash memory, or a mixture of both. For the purposes of this description, a general reference to memory refers to all memory accessible by the processor 601, 701, including internal memory 602, 702, removable memory plugged into the device, and memory within the processor 601, 701 itself.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The foregoing method descriptions and the process flow diagrams are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The hardware used to implement the various illustrative logics, logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some steps or methods may be performed by circuitry that is specific to a given function.

In one or more exemplary aspects, the functions described may be implemented in hardware, software, firmware, or any combination thereof. If implemented in software, the functions may be stored on or transmitted over as one or more instructions or code on a computer-readable medium. The steps of a method or algorithm disclosed herein may be embodied in a processor-executable software module executed which may reside on a non-transitory computer-readable medium. Non-transitory computer-readable media includes any available media that may be accessed by a computer. By way of example, and not limitation, such non-transitory computer-readable media may comprise RAM, ROM, EEPROM, CD-ROM or other optical disk storage, magnetic disk storage or other magnetic storage devices, or any other medium that may be used to carry or store desired program code in the form of instructions or data structures and that may be accessed by a computer. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and/or instructions on a non-transitory processor-readable readable medium and/or non-transitory computer-readable medium, which may be incorporated into a computer program product.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A method of enhancing data transmission in an ATSC M/H wireless communication link, comprising:
turbo encoding a data block for transmission;
scheduling a plurality of portions of the turbo-coded data block for transmission during respectively corresponding transmit intervals that are temporally separated from one another; and
transmitting said portions of the turbo-coded data block during the respectively corresponding transmit intervals according to said scheduling.

2. The method of claim 1, wherein said transmit intervals are equal in length.

3. The method of claim 2, wherein said transmit intervals are equally separated from one another temporally.

4. The method of claim 1, wherein said transmit intervals are equally separated from one another temporally.

5. The method of claim 1, wherein each of said portions contains a plurality of bits.

6. The method of claim 1, wherein each of said portions consists of a single bit.

7. The method of claim 6, further comprising re-ordering bits of said turbo-coded block before said scheduling.

8. The method of claim 1, further comprising re-ordering bits of said turbo-coded block before said scheduling.

9. The method of claim 1, wherein turbo encoding a data block for transmission is accomplished using one of a parallel concatenation Turbo encoder, a Serial concatenation Turbo encoder, a convolutional encoder, and a low-density parity-check (LDPC) encoder.

10. An apparatus for processing ATSC M/H data packets to improve transport over an ATSC M/H wireless communication link, comprising:
a turbo encoder configured to turbo encode data packets for transmission into a data block;
a scheduler configured to schedule a plurality of portions of the turbo-coded data block for transmission during respectively corresponding transmit intervals that are temporally separated from one another; and
a transmitter coupled to said scheduler and configured to transmit said portions of the turbo-coded data block during the respectively corresponding transmit intervals according to said scheduling.

11. The apparatus of claim 10, wherein the turbo encoder is selected from the group of a parallel concatenation Turbo encoder, a Serial concatenation Turbo encoder, a convolutional encoder, and a low-density parity-check (LDPC) encoder.

12. The apparatus of claim 10, wherein the scheduler is configured to schedule the plurality of portions of the turbo-coded data block into transmit intervals of equal length.

13. The apparatus of claim 12, wherein the scheduler is configured to schedule the plurality of portions of the turbo-coded data block so that the transmit intervals are equally separated from one another temporally.

14. The apparatus of claim 10, wherein the scheduler is configured to schedule the plurality of portions of the turbo-coded data block so that the transmit intervals are equally separated from one another temporally.

15. The apparatus of claim 10, wherein the scheduler is configured to schedule the plurality of portions of the turbo-coded data block so that each of said portions contains a plurality of bits.

16. The apparatus of claim 10, wherein the scheduler is configured to schedule the plurality of portions of the turbo-coded data block so that each of said portions consists of a single bit.

17. The apparatus of claim 16, further comprising an interleaver configured to receive the turbo-coded block, re-order bits of the portions of the turbo-coded block, and providing interleaved portions of the turbo-coded block to the scheduler for scheduling.

18. The apparatus of claim 10, further comprising an interleaver configured to receive the turbo-coded block, re-order bits of the portions of the turbo-coded block, and providing interleaved portions of the turbo-coded block to the scheduler for scheduling.

19. An apparatus for processing ATSC M/H data packets to improve transport over an ATSC M/H wireless communication link, comprising
means for turbo encoding data packets for transmission into a data block;
means for scheduling a plurality of portions of the turbo-coded data block for transmission during respectively corresponding transmit intervals that are temporally separated from one another; and
means for transmitting said portions during the respectively corresponding transmit intervals according to said scheduling.

20. The apparatus of claim 19, wherein the means for turbo encoding is selected from the group of a parallel concatenation Turbo encoder, a Serial concatenation Turbo encoder, a convolutional encoder, and a low-density parity-check (LDPC) encoder.

21. The apparatus of claim 19, wherein means for scheduling a plurality of portions of the turbo-coded data block for transmission comprises means for scheduling a plurality of portions of the turbo-coded data block for transmission in transmit intervals that are equal in length.

22. The apparatus of claim 21, wherein means for scheduling a plurality of portions of the turbo-coded data block for transmission comprises means for scheduling the plurality of portions of the turbo-coded data block for transmission in transmit intervals that are equally separated from one another temporally.

23. The apparatus of claim 19, wherein means for scheduling a plurality of portions of the turbo-coded data block for transmission comprises means for scheduling the plurality of portions of the turbo-coded data block for transmission in transmit intervals that are equally separated from one another temporally.

24. The apparatus of claim 19, wherein means for scheduling a plurality of portions of the turbo-coded data block for transmission comprises means for scheduling the plurality of portions of the turbo-coded data block for transmission so that each portion contains a plurality of bits.

25. The apparatus of claim 19, wherein means for scheduling a plurality of portions of the turbo-coded data block for transmission comprises means for scheduling the plurality of portions of the turbo-coded data block for transmission so that each portion contains a single bit.

26. The apparatus of claim 25, further comprising means for re-ordering bits of the turbo-coded block before scheduling.

27. The apparatus of claim 19, further comprising means for re-ordering bits of the turbo-coded block before scheduling.

28. A non-transitory computer-readable storage medium having stored thereon computer-executable instructions configured to cause a computer to perform operations comprising:
turbo encoding ATSC M/H data packets for transmission into a data block;
scheduling a plurality of portions of the turbo-coded ATSC M/H data block for transmission during respectively corresponding transmit intervals that are temporally separated from one another; and
transmitting the portions of the ATSC M/H turbo-coded data block during the respectively corresponding transmit intervals according to said scheduling.

29. The non-transitory computer-readable storage medium of claim 28, wherein the stored computer-executable instructions are configured to cause a computer to perform operations such that scheduling a plurality of portions of the turbo-coded ATSC M/H data block for transmission comprises scheduling the plurality of portions of the turbo-coded data block for transmission in transmit intervals that are equal in length.

30. The non-transitory computer-readable storage medium of claim 29, wherein the stored computer-executable instructions are configured to cause a computer to perform operations such that scheduling a plurality of portions of the turbo-coded ATSC M/H data block for transmission comprises scheduling the plurality of portions of the turbo-coded data block for transmission in transmit intervals that are equally separated from one another temporally.

31. The non-transitory computer-readable storage medium of claim 28, wherein the stored computer-executable instructions are configured to cause a computer to perform operations such that scheduling a plurality of portions of the turbo-coded ATSC M/H data block for transmission comprises scheduling the plurality of portions of the turbo-coded data block for transmission in transmit intervals that are equally separated from one another temporally.

32. The non-transitory computer-readable storage medium of claim 28, wherein the stored computer-executable instructions are configured to cause a computer to perform operations such that scheduling a plurality of portions of the turbo-coded ATSC M/H data block for transmission comprises scheduling the plurality of portions of the turbo-coded data block for transmission so that each portion contains a plurality of bits.

33. The non-transitory computer-readable storage medium of claim 28, wherein the stored computer-executable instructions are configured to cause a computer to perform operations such that scheduling a plurality of portions of the turbo-coded ATSC M/H data block for transmission comprises scheduling the plurality of portions of the turbo-coded data block for transmission so that each portion contains a single bit.

34. The non-transitory computer-readable storage medium of claim 33, wherein the stored processor-executable instructions are configured to cause a computer to perform operations further comprising:
re-ordering bits of said turbo-coded block before said scheduling.

35. The non-transitory computer-readable storage medium of claim 28, wherein the stored processor-executable instructions are configured to cause a computer to perform operations further comprising:
re-ordering bits of said turbo-coded block before said scheduling.

36. The non-transitory computer-readable storage medium of claim 28, wherein the stored computer-executable instructions are configured to cause a computer to perform operations such that turbo-encoding ATSC M/H data packets is accomplished using one of a parallel concatenation Turbo encoder, a Serial concatenation Turbo encoder, a convolutional encoder, and a low-density parity-check (LDPC) encoder.
